(19) United States
(12) Patent Application Publication
(10) Pub. No.: US 2014/0141548 A1
(43) Pub. Date: May 22, 2014

(54) METHOD OF MANUFACTURING A METAL CLAD CIRCUIT BOARD

(71) Applicant: Tyco Electronics Corporation, Berwyn, PA (US)

(72) Inventors: Matthew Edward Mostoller, Hummelstown, PA (US); Robert D. Rix, Hershey, PA (US); Michael F. Laub, Enola, PA (US); Marjorie K. Myers, Mount Wolf, PA (US); Dean Perronne, Barto, PA (US); Miguel Morales, Fremont, CA (US); Charles Randall Malstrom, Lebanon, PA (US); Leonard H. Radzilowski, Palo Alto, CA (US)

(73) Assignee: Tyco Electronics Corporation, Berwyn, PA (US)

(21) Appl. No.: 14/083,153

(22) Filed: Nov. 18, 2013

Related U.S. Application Data
(62) Division of application No. 13/215,947, filed on Aug. 23, 2011, now abandoned.

(51) Int. Cl. H01L 33/64

(52) U.S. Cl. CPC H01L 33/644
USPC 438/26; 29/25.42

(57) ABSTRACT

A metal clad circuit board includes a metal substrate. A dielectric layer is applied to the metal substrate. A conductive seed layer is printed on the dielectric layer. A conductive circuit layer is plated onto the conductive seed layer. Optionally, the conductive seed layer may be inkjet printed on the dielectric layer. Alternatively, the conductive seed layer may be pad printed on the dielectric layer. Optionally, the dielectric layer may be powder coated to the metal substrate. The dielectric layer may include polymers and fillers compression molded to the metal substrate. Optionally, the conductive circuit layer may be electroplated to the conductive seed layer. Optionally, a solder mask may be applied over the conductive circuit layer.

### CROSS REFERENCE TO RELATED APPLICATIONS

This application is a divisional application of U.S. patent application Ser. No. 13/215,947 filed Aug. 23, 2011 and titled METAL CLAD CIRCUIT BOARD, the subject matter of which is herein incorporated by reference in its entirety.

### BACKGROUND OF THE INVENTION

The subject matter herein relates generally to thermally conductive substrates, and more particularly to metal clad circuit boards.

Currently, within the solid state lighting market, light emitting diodes (LEDs) are mounted on metal clad circuit boards. The metal clad circuit boards are useful in high power LED solutions for adequate heat spreading or heat sinking of the LEDs.

Metal clad circuit boards typically include a base material, such as an aluminum sheet, that has an electrically insulative, but somewhat thermally conductive layer to isolate the base aluminum from copper traces which are on top of the insulative layer. The metal clad circuit boards are manufactured by a subtractive process, much like a traditional printed circuit board made from a glass epoxy material, such as an FR4 circuit board. A copper sheet is applied to the insulative layer, and the copper sheet is etched away to create the necessary circuit traces. Such a process is referred to as a subtractive process to remove the copper from the copper sheet applied to the circuit board substrate via etching or machining to achieve the circuit trace geometry. Typically, a solder mask is placed on top of the traces.

Circuit boards manufactured by a subtractive process are not without disadvantages. For instance, every time a new geometry or circuit is required, a photo-resist etch plate needs to be created. This requires time and money investment before the circuit geometry can be made.

A need remains for a metal clad circuit board that can be manufactured in a cost effective and reliable manner. A need remains for a metal clad circuit board that has effective heat dissipation.

### BRIEF DESCRIPTION OF THE INVENTION

In one embodiment, a metal clad circuit board is provided having a metal substrate. A dielectric layer is applied to the metal substrate. A conductive seed layer is printed on the dielectric layer. A conductive circuit layer is plated onto the conductive seed layer. Optionally, the conductive seed layer may be inkjet printed on the dielectric layer. Alternatively, the conductive seed layer may be pad printed on the dielectric layer. Optionally, the dielectric layer may be powder coated to the metal substrate. The dielectric layer may include polymers and fillers compression molded to the metal substrate. Optionally, the conductive circuit layer may be electroplated to the conductive seed layer. Optionally, a solder mask may be applied over the conductive circuit layer.

In an exemplary embodiment, the conductive seed layer and the conductive circuit layer are applied to the dielectric layer by an additive process. Optionally, neither the conductive seed layer nor the conductive circuit layer is etched from a copper sheet.

Optionally, the metal substrate may include an aluminum substrate having a first surface and a second surface, where the first surface is mounted to a heat sink and the dielectric layer is applied to the second surface. The metal substrate may be at least half of a total thickness of the metal clad circuit board. A solid state lighting device may be mechanically and electrically connected to the conductive circuit layer.

In another embodiment, a metal clad circuit board is provided having a metal substrate. A dielectric layer is applied to the metal substrate. A conductive seed layer is printed on the dielectric layer. A conductive circuit layer is plated onto the conductive seed layer. A solid state lighting device is mechanically and electrically connected to the conductive circuit layer.

In a further embodiment, a metal clad circuit board is provided having a metal substrate. A dielectric layer is applied to the metal substrate. The dielectric layer is powder coated onto the metal substrate. A conductive seed layer is printed on the dielectric layer. A conductive circuit layer is plated onto the conductive seed layer.

### BRIEF DESCRIPTION OF THE DRAWINGS

FIG. 1 is a perspective view of an LED assembly formed in accordance with an exemplary embodiment.

FIG. 2 is a cross-sectional view of a metal clad circuit board formed in accordance with an exemplary embodiment for the LED assembly shown in FIG. 1.

FIG. 3 is a flow chart showing a method of manufacturer of a metal clad circuit board.

FIG. 4 illustrates a dielectric layer of the metal clad circuit board being applied to a metal substrate of the metal clad circuit board in accordance with an exemplary embodiment.

FIG. 5 illustrates a conductive seed layer of the metal clad circuit board being applied to the dielectric layer in accordance with an exemplary embodiment.

FIG. 6 illustrates an exemplary thermal performance chart, illustrating thermal resistivity levels of various dielectrics, for use as the dielectric layer having various thicknesses.

### DETAILED DESCRIPTION OF THE INVENTION

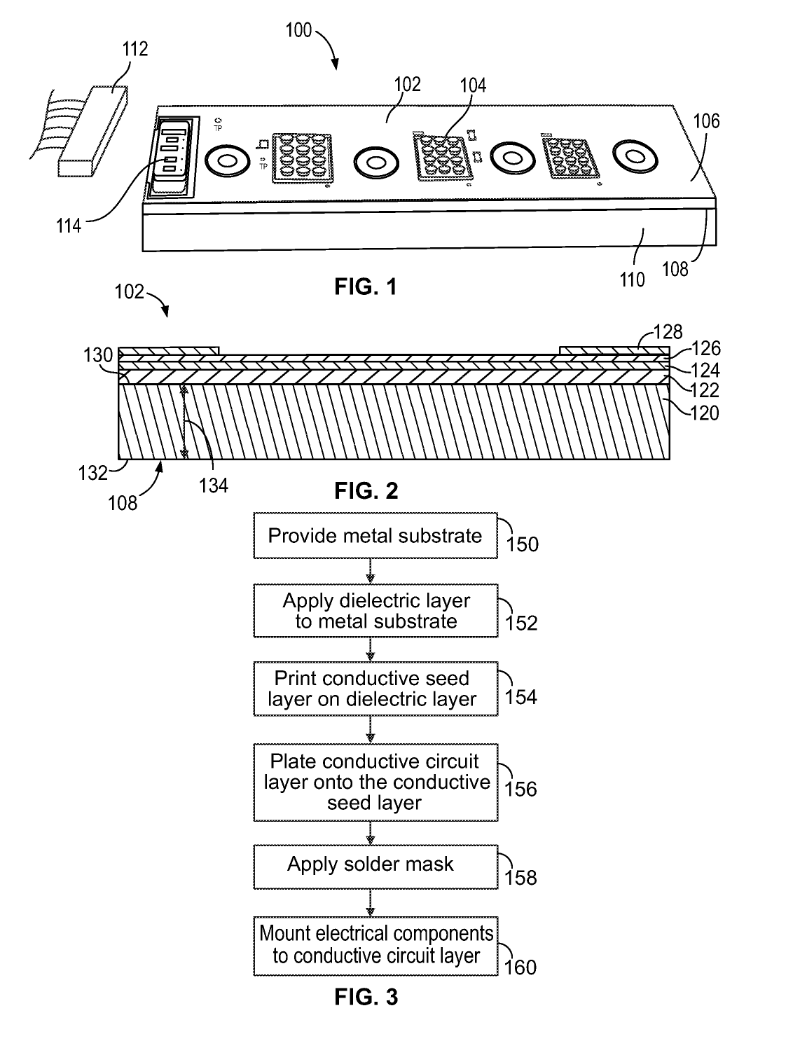

FIG. 1 is a perspective view of an LED assembly 100 formed in accordance with an exemplary embodiment. The LED assembly 100 includes a metal clad circuit board 102 having a plurality of LEDs 104 mounted to a top surface 106 of the metal clad circuit board 102. A bottom surface 108 of the metal clad circuit board 102 is mounted to a heat sink 110. The metal clad circuit board 102 may be used in other applications other than in an LED assembly 100. For example, the metal clad circuit board 102 may be used as part of a power device, an antenna, or other applications.

A power connector 112 is configured to be electrically connected to the LED assembly 100 to supply power to the LED assembly 100. The metal clad circuit board 102 includes a plurality of power pads 114 proximate to an edge of the metal clad circuit board 102. The power connector 112 is coupled to the metal clad circuit board 102 such that the power connector 112 engages the power pads 114. Power is supplied to the metal clad circuit board 102 via the power pads 114.

The metal clad circuit board 102 includes a metal substrate that provides heat transfer to the heat sink 110 to cool the components mounted to the metal clad circuit board 102, such as the LEDs 104. The metal substrate of the metal clad circuit board 102 provides better thermal transfer than other types of circuit boards, such as circuit boards manufactured from glass epoxy or FR4 materials. The metal substrate of the metal clad circuit board 102 provides a mechanically robust substrate that is not as fragile as other types of circuit boards. The metal clad circuit board 102 provides low operating temperatures for the LEDs 104 and has increased thermal efficiency for dissipating heat from the LEDs 104. The metal clad circuit board 102 has high durability and may have a reduced size by limiting the need for an additional heat transfer layer.

The metal clad circuit board 102 may have a variety of shapes of sizes depending on the particular application. In the illustrated embodiment, the metal clad circuit board 102 is elongated and rectangular in shape. The LEDs 104 are arranged in line along the top surface 106. Alternative configurations of the LEDs 104 are possible in alternative embodiments. Any number of LEDs 104 may be provided on the top surface 106 depending on the particular application and lighting effect desired. The metal clad circuit board 102 may be generally circular in shape in an alternative embodiment. The LED assembly 100 may include other electronic components on the top surface 106 of the metal clad circuit board 102. For example, the LED assembly 100 may include other electronic components, such as capacitors, resistors, sensors, and the like on the top surface 106.

FIG. 2 is a cross-sectional view of the metal clad circuit board 102 formed in accordance with an exemplary embodiment. The metal clad circuit board 102 includes a metal substrate 120, a dielectric layer 122 applied to the metal substrate 120, a conductive seed layer 124 printed on the dielectric layer 122, a conductive circuit layer 126 plated onto the conductive seed layer 124, and a solder mask layer 128 applied over the conductive circuit layer 126. The different layers are defined as having different characteristics. The different layers may be formed from different materials. The different layers may be deposited on the other layer. The metal clad circuit board 102 may have other layers in alternative embodiments, which may be interspersed between the layers identified above. A layer can be said to be deposited on, applied on, applied to, applied over and the like with respect to another layer, while having other layers interspersed therebetween. A layer is said to be directly deposited on, directly applied on, directly applied to, directly over and the like with respect to another layer when such layer directly engages and no other layer is interspersed therebetween. The metal clad circuit board 102 may be manufactured with fewer layers in alternative embodiments.

The metal substrate 120 is provided at the bottom surface 108 of the metal clad circuit board 102. The metal substrate 120 extends between a first surface 130 and a second surface 132. The first surface 130 is configured to be mounted to the heat sink 110 (shown in FIG. 1). Optionally, a thermal interface material (not shown) may be applied to the first surface 130 for interfacing with the heat sink 110. The dielectric layer 122 is applied to the second surface 132. The metal substrate 120 has a thickness 134 measured between the first and second surfaces 130, 132.

The metal substrate 120 is fabricated from a material having a high thermal efficiency, such as an aluminum material, a copper material, and the like. The metal substrate 120 efficiently transfers heat from the components mounted to the metal clad circuit board 102, such as the LEDs 104 (shown in FIG. 1). The thickness 134 may be at least half the overall thickness of the metal clad circuit board 102 measured between the top surface 106 and the bottom surface 108. Having a thick metal substrate 120 provides rigidity and robustness to the metal clad circuit board 102.

The dielectric layer 122 is positioned between the metal substrate 120 and the conductive seed layer 124. The dielectric layer 122 electrically isolates the metal substrate 120 from the conductive seed layer 124. The dielectric layer 122 has a low thermal resistance so that effective thermal transfer can occur to the metal substrate 120. The thickness of the dielectric layer 122 as well as the type of material used for the dielectric layer 122 may affect the thermal conductivity or thermal resistivity properties of the dielectric layer 122. The dielectric layer 122 is relatively thin to allow adequate thermal transfer through the dielectric layer 122 to the metal substrate 120. In an exemplary embodiment, the dielectric layer 122 is between approximately 0.002″ and 0.003″. Other thicknesses of the dielectric layer 122 are possible in alternative embodiments.

The dielectric layer 122 needs to maintain adequate dielectric properties to maintain electrical isolation between the metal substrate 120 and the conductive seed layer 124 and/or the conductive circuit layer 124. For example, the dielectric layer 122 may need to be rated to withstand a predetermined voltage level, such as 2500 volts. The thickness of the dielectric layer 122 as well as the type of material used for the dielectric layer 122 may affect the dielectric properties and effectiveness of the dielectric layer 122. Different types of dielectric materials may be used in various embodiments. In an exemplary embodiment, the dielectric layer 122 is manufactured from polymer particles. Optionally, the dielectric layer 122 may include fillers or other particles mixed in with the polymers to change properties of the dielectric layer 122, such as the thermal efficiency of the dielectric layer 122. For example, particles such as alumina or boron nitride particles may be added to the polymer particles to make the dielectric layer 122 more thermally conductive. Other types of fillers may be added to the mixture to change other characteristics of the dielectric layer 122.

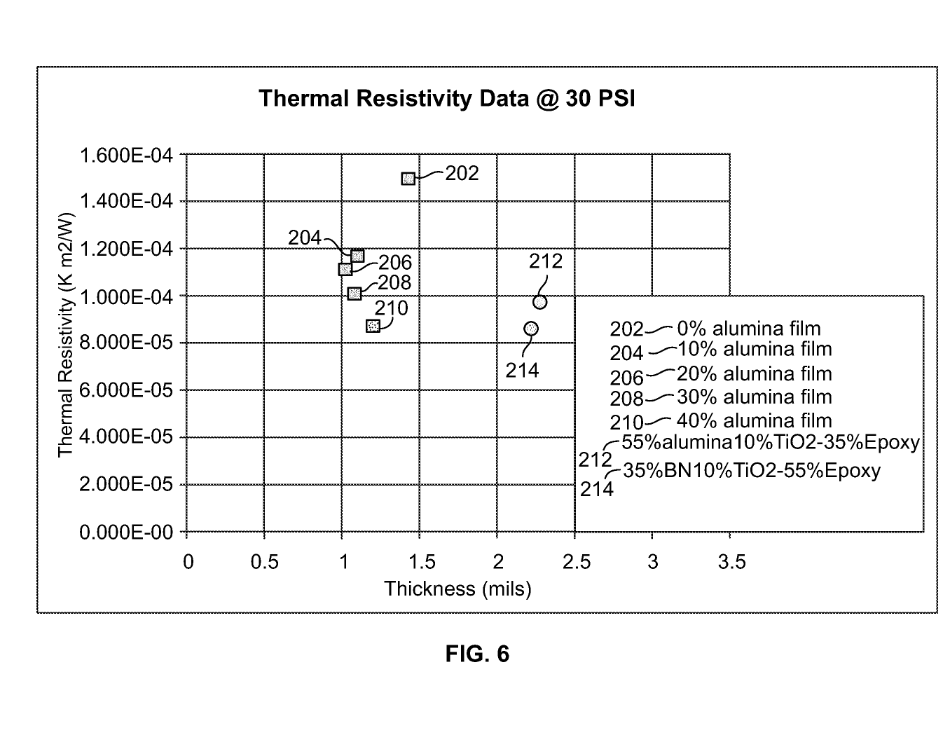

FIG. 6 illustrates an exemplary thermal performance chart, illustrating thermal resistivity levels of various dielectrics 202-214, for use as the dielectric layer 122 having various thicknesses. In the illustrated embodiment, the dielectric thicknesses range from approximately 0.001″ to 0.0025″. Other thicknesses are possible in alternative embodiments. The dielectrics 202-214 may be powders, films, epoxys, or come in other forms. The dielectrics 202-214 have different concentrations of materials. Other types of dielectrics may be used in alternative embodiments, and the dielectrics 202-214 illustrated in FIG. 6 are merely exemplary.

Returning to FIG. 2, the dielectric layer 122 may be applied to the metal substrate 120 using different processes. In an exemplary embodiment, the dielectric layer 122 is powdered coated to the metal substrate 120. The dielectric layer 122 includes fine powder particles composed of a mixture of polymer and fillers that may be compression molded onto the metal substrate 120. Different types of fillers may be used to change the characteristics of the dielectric layer 122.

In an alternative embodiment, the dielectric layer 122 may be an epoxy applied to the metal substrate 120. For example, the dielectric layer 122 may include a liquid suspension having a mixture of polymers, fillers and solvent that is spread onto a silicone coated Mylar film, which is partially cured to an intermediate stage then transferred to the metal substrate 120. The mixture is then compression molded to the metal substrate 120. The liquid suspension, when cured, may have a uniform and/or non-porous surface for good contact with the metal substrate 120. In another alternative embodiment, the dielectric layer 122 may include a film, such as a Mylar film, that is applied to the metal substrate 120.

The conductive seed layer 124 is applied to the dielectric layer 122. For example, the conductive seed layer 124 may include conductive ink that is printed onto the dielectric layer 122. Optionally, the conductive ink may be a silver ink. The conductive seed layer 124 may include additives, such as adhesion promoters. In an exemplary embodiment, the conductive ink is printed onto the dielectric layer 122 using an inkjet printing process. Alternatively, the conductive ink may be applied using pad printing or screen printing onto the dielectric layer 122. Other processes may be used to apply the conductive ink onto the dielectric layer 122 in alternative embodiments.

The conductive seed layer 124 forms base conductive traces on the metal clad circuit board 102. Once the base conductive traces have been applied, the base conductive traces are over-plated with copper or another conductive material, to create the conductive circuit layer 126. The copper may be deposited quickly. The conductive circuit layer 126 may be applied as a thick layer to enhance current carrying capacity. The base conductive traces may be over-plated with other elements, such as tin to provide environmental protection and a solderable surface. The tin may be applied during a plating process to create part of the conductive circuit layer 126. The conductive seed layer 124 and the conductive circuit layer 126 together define conductive traces of the metal clad circuit board 102.

In an exemplary embodiment, the conductive circuit layer 126 is electroplated to the base conductive traces defined by the conductive seed layer 124 to form the conductive circuit layer 126. The conductive circuit layer 126 has a much higher current carrying capability than the conductive seed layer 124, which increases the current carrying capability of the metal clad circuit board 102. For example, the conductive seed layer 124 has enough current carrying capability to allow the electroplating of the conductive circuit layer 126. The conductive circuit layer 126, which is electroplated to the conductive seed layer 124, has enough current carrying capability for the particular application, such as powering the LEDs 104 (shown in FIG. 1).

In an exemplary embodiment, to achieve electroplating, all of the conductive traces need to be commoned as part of one circuit. The conductive seed layer 124 defines such a circuit, which is then electroplated to form the conductive circuit layer 126. Predetermined areas, referred to as circuit commons, need to be removed after the electroplating process, to define the conductive traces of the metal clad circuit board 102. The circuit commons may be removed by a milling process, a laser removal process, a chemical removal process, an electro-machining process, and the like.

In an alternative embodiment, the conductive circuit layer 126 may be electroless plated. The metal clad circuit board 102 may be provided with or without the conductive seed layer 124 in such embodiments. Other types of plating of the conductive circuit layer 126 may be utilized in alternative embodiments, such as mechanical plating using heat and pressure, other types of chemical plating, metalizing, and the like.

The solder mask layer 128 is selectively applied over the conductive circuit layer 126 to protect the conductive circuit layer 126, such as from corrosion. Portions of the conductive circuit layer 126 are exposed through the solder mask layer 128 to allow for soldering of components to the conductive circuit layer 126. In an exemplary embodiment, the solder mask layer 128 is applied to the metal clad circuit board 102 using a pad printing process. Alternatively, the solder mask layer 128 may be applied using other processes, such as an inkjet printing process or other processes for applying the solder mask layer 128.

FIG. 3 is flow chart showing a method of manufacturing a metal clad circuit board, such as the metal clad circuit board 102 shown in FIGS. 1-2. The method includes providing 150 a metal substrate. The metal substrate may be cut from an aluminum panel to a predetermined size. The metal substrate may be manufactured in a different way and/or from a different material.

The method includes applying 152 a dielectric layer to the metal substrate. The dielectric layer may be applied to the metal substrate by powder coating a powder mixture to a surface of the metal substrate. The powder mixture may be compression molded to the metal substrate. In an exemplary embodiment, the metal substrate may be held within a device having a base with a silicone coated Mylar sheet between the base and the metal substrate. The loose powder mixture may be poured onto the metal substrate and another silicone coated Mylar film may be placed over the powder mixture. A steel plate may be pressed onto the assembly using a high force to apply the dielectric layer to the metal substrate. The sample may be hot pressed to the metal substrate using heat and pressure to bond the dielectric layer the metal substrate. The Mylar films may be pulled away from the pressed sample after the dielectric layer is applied to the metal substrate.

In an alternative embodiment, the dielectric layer may be formed by forming a liquid suspension coating that is cured and applied to the metal substrate. For example, a Mylar film may be placed on the bed of a doctor blade coater. A bead of epoxy fabricated from polymers, fillers and solvent is spread on the Mylar film in front of the blade. The epoxy is spread across the film by the blade to create a sample. The sample is cured in an oven to an intermediate or partial curing stage. The intermediately cured sample may be cut to size and placed in contact with the metal substrate. The sample may be hot pressed to the metal substrate using heat and pressure to bond the dielectric layer the metal substrate. Other types of devices may be used to form the sample. For example, a draw down coater or a slot die coater may be used to create the sample. Other types of devices, other than coaters, may be used to create a sample.

The method includes printing 154 a conductive seed layer on the dielectric layer. The conductive seed layer includes conductive ink that is printed onto the dielectric layer. The conductive ink may be printed using an inkjet printer in one embodiment. In another embodiment, the conductive ink may be printed onto the dielectric layer using a pad printing process or a screen printing process. The conductive seed layer defines base conductive traces on the dielectric layer. The conductive seed layer may be applied to the dielectric layer by other processes other than printing in alternative embodiments.

In an exemplary embodiment, to enhance the conductive properties of the base conductive traces, a conductive circuit layer may be plated 156 onto the conductive seed layer. In an exemplary embodiment, the conductive circuit layer is plated onto the conductive seed layer using an electroplating process. Other plating processes may be used in alternative embodiments to apply the conductive circuit layer to the conductive seed layer. In other alternative embodiments, the conductive circuit layer may be added to the dielectric layer without the use of printing the conductive seed layer.

During the electroplating process, the sample, having the metal substrate, the dielectric layer and the conductive seed layer may be placed into a fluid bath having conductive particles. The conductive seed layer is electrically charged and current is applied to the conductive seed layer. The electroplating process deposits metallic particles onto the conductive seed layer. For example, copper and/or tin particles may be attracted to the conductive seed layer by the conductive ink. The copper and/or tin particles are attached to the conductive ink, thus plating the conductive seed layer. Other types of particles may be plated in addition to, or in the alternative to, the copper and/or tin particles. The copper particles of the conductive circuit layer increase the current carrying capability of the conductive traces. The tin particles provide environmental protection and a solderable surface for the conductive traces.

The method includes applying 158 a solder mask over the conductive traces. The solder mask may be selectively applied over portions of the conductive traces to protect the conductive traces from corrosion. Portions of the conductive traces may be exposed by the solder mask to allow for soldering of electrical components to the conductive traces. For examples, LEDs or other electrical components may be soldered to the conductive traces. The solder mask may be applied using a pad printing process. The solder mask may be applied using an alternative process, such as an inkjet printing process.

Electrical components, such as LEDs or other electrical components are mounted 160 to the conductive traces of the conductive circuit layer. The electrical components may be mounted by soldering the electrical components to the conductive traces. The solder mask exposes mounting pads for mounting the electrical components to the conductive traces.

Optionally, many metal clad circuit boards may be manufactured at one time as part of a panel. The method may include separating the individual metal clad circuit boards from one another. For example, the metal clad circuit boards may be routed or scored and broken from other metal clad circuit boards.

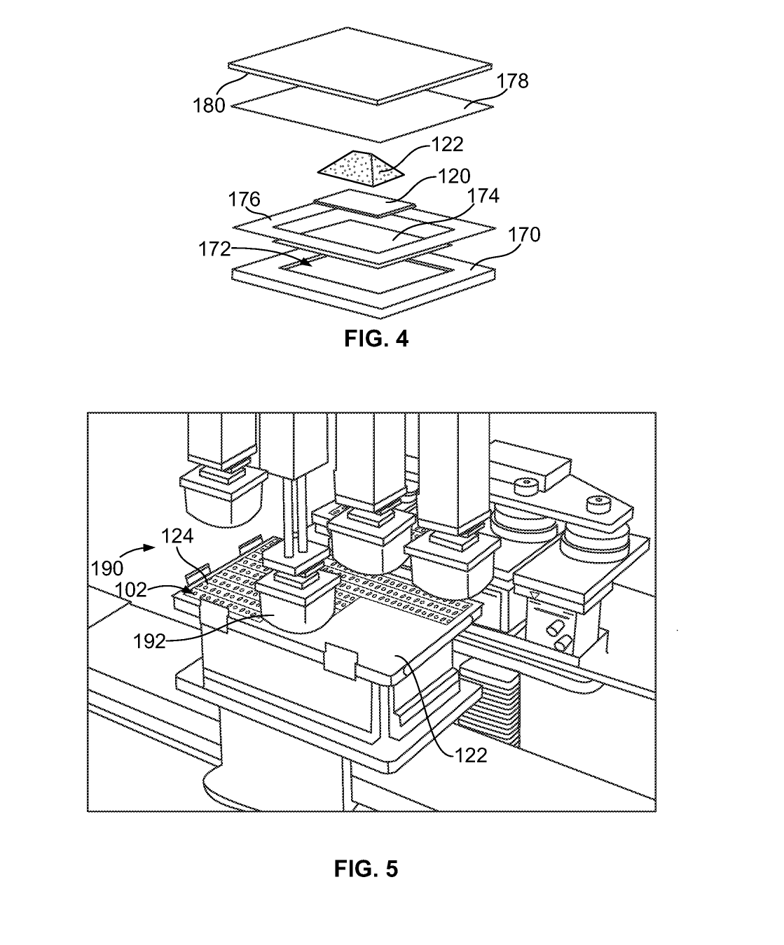

FIG. 4 illustrates the dielectric layer 122 being applied to the metal substrate 120. A base 170 is provided having a cavity 172 that receives the metal substrate 120 and the dielectric layer 122. The cavity 172 has a depth that may be equal to a desired thickness of the metal substrate 120 and the dielectric layer 122.

A Mylar film 174 is arranged on the base 170 within the cavity 172. The metal substrate 120 may be placed on the Mylar film 174. A frame 176 operates as a shim to control the thickness of the metal substrate 120 and the dielectric layer 122. The frame 176 adds additional thickness to the cavity 172.

The dielectric layer 122 is placed on the metal substrate 120. In an exemplary embodiment, the dielectric layer 122 includes a powder mixture of polymers and fillers that are poured onto the metal substrate 120. Alternatively, the dielectric layer 122 may be a film or epoxy that is placed on the metal substrate 120. A Mylar film 178 is placed over the dielectric layer 122.

A top plate 180 is lowered onto the Mylar film 178 to press the dielectric layer 122 against the metal substrate 120. In an exemplary embodiment, the top plate 180 and/or base 170 are heated to help bond the dielectric layer 122 to the metal substrate 120 during the compression process. The top plate 180 is pressed downward, thus compression molding the dielectric layer 122 to the metal substrate 120.

FIG. 5 illustrates the conductive seed layers 124 being printed on the metal clad circuit board 102. A pad printing machine 190 is provided having pads 192 that may be dipped into conductive ink. The conductive ink is deposited on the pad 192 in a predetermined pattern. The pad 192 is pressed onto the dielectric layer 122 of the metal clad circuit board 102 and the conductive ink is then deposited on the dielectric layer 122. In an alternative embodiment, rather than a pad printing machine, the conductive ink may be applied using an ink jet printer or a screen printer.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A method of manufacturing a metal clad circuit board, said method comprising:
providing a metal substrate;
applying a dielectric layer to the metal substrate;
printing a conductive seed layer on the dielectric layer; and
plating a conductive circuit layer on the conductive seed layer.

2. The method of claim 1, wherein said printing comprises inkjet printing a conductive seed layer on the dielectric layer.

3. The method of claim 1, wherein said printing comprises pad printing a conductive seed layer on the dielectric layer.

4. The method of claim 1, wherein said printing comprises screen printing a conductive seed layer on the dielectric layer.

5. The method of claim 1, wherein said plating comprises electroplating a conductive circuit layer onto the conductive seed layer.

6. The method of claim 1, wherein said applying comprises powder coating a dielectric layer on the metal substrate.

7. The method of claim 1, further comprising mounting the metal substrate to a heat sink.

8. The method of claim 1, further comprising applying a solder mask over the conductive circuit layer.

9. The method of claim 1, further comprising coupling a solid state lighting device to the conductive circuit layer.

10. A method of manufacturing a metal clad circuit board, said method comprising:
providing a metal substrate;
applying a dielectric layer directly on the metal substrate;
printing a conductive seed layer directly on the dielectric layer; and
plating a conductive circuit layer directly on the conductive seed layer.

11. The method of claim 10, wherein said printing comprises inkjet printing a conductive seed layer directly on the dielectric layer.

12. The method of claim 10, wherein said printing comprises pad printing a conductive seed layer directly on the dielectric layer.

13. The method of claim 10, wherein said printing comprises screen printing a conductive seed layer directly on the dielectric layer.

14. The method of claim 10, wherein said plating comprises electroplating a conductive circuit layer directly onto the conductive seed layer.

15. The method of claim 10, wherein said applying comprises powder coating a dielectric layer directly on the metal substrate.

16. The method of claim 10, further comprising mounting the metal substrate to a heat sink.

17. The method of claim 10, further comprising applying a solder mask over the conductive circuit layer.

18. The method of claim 10, further comprising coupling a solid state lighting device to the conductive circuit layer.
